(19) United States
(12) Patent Application Publication
(10) Pub. No.: US 2005/0098710 A1
(43) Pub. Date: May 12, 2005

(54) Image sensor package

(76) Inventors: Jackson Hsieh, Hsinchu Hsien (TW); Jichen Wu, Hsinchu Hsien (TW); Channing Wel, Hsinchu Hsien (TW); Bird Lin, Hsinchu Hsien (TW)

Correspondence Address: PRO-TECHTOR INTERNATIONAL, 20775 Norada Court, Saratoga, CA, 95070-3018, US

(21) Appl. No.: 10/705,378

(22) Filed: Nov. 10, 2003

(51) Int. Cl. H01L 27/00

(52) U.S. Cl. 250/208.1

(57) ABSTRACT

The invention provides an image sensor package including a substrate, a frame layer, a photosensitive chip, a plurality of wires, and a transparent layer. The substrate includes plural metal sheets, which are spaced apart and arranged in an alternating manner, each of the metal sheets have a first board and a second board positioned at different heights, the thicken of outside ends of the first board are smaller than the inside ends of the first board, a encapsulate layer encapsulated the plural metal sheets to form a upper surface and a lower surface, so that the outside ends of the first board and the second board are exposed from the encapsulate layer. The frame layer is formed around and under the substrate to form a cavity with the substrate. The photosensitive chip is positioned on upper surface of the substrate and within the cavity. The wires are electrically connecting the outside ends of the first boards to the photosensitive chip. The transparent layer placed on the frame layer to cover the photosensitive chip.

### BACKGROUND OF THE INVENTION

1. Field of the Invention

The invention relates to an image sensor package, and more specifically to an image sensor which can be manufactured conveniently and improve the product yield.

2. Description of the Related Art

Referring to FIG. 1, is a patent of an image sensor (U.S. application Ser. No. 10/146,997) of Kingpak corporation includes a substrate 10 having plural metal sheets 12, which are spaced apart and arranged in an alternating manner, each of the metal sheets 12 have a first board 14 and a second board 16 positioned at different heights. A frame layer 18 is formed around and under the substrate to form a cavity 20 with the substrate 10. A photosensitive chip 22 is positioned within the cavity 20. A plurality of wires are electrically connected the first board 14 of the metal sheets 12 to the photosensitive chip 22. A transparent layer 26 is placed on the frame layer 18 to cover the photosensitive chip 22.

### SUMMARY OF THE INVENTION

It is therefore an object of the invention to provide an image sensor package capable of simplifying the packaging processes to decrease the manufacturing cost.

It is another object of the invention to provide an image sensor package capable of increasing the production yield to decrease the packaging cost.

To achieve the above-mentioned objects, the present invention includes a frame layer, a photosensitive chip, a plurality of wires, and a transparent layer. The substrate includes plural metal sheets, which are spaced apart and arranged in an alternating manner, each of the metal sheets have a first board and a second board positioned at different heights, the thicken of outside ends of the first board are smaller than the inside ends of the first board, a encapsulate layer encapsulated the plural metal sheets to form a upper surface and a lower surface, so that the outside ends of the first board and the second board are exposed from the encapsulate layer. The frame layer is formed around and under the substrate to form a cavity with the substrate. The photosensitive chip is positioned on upper surface of the substrate and within the cavity. The wires are electrically connecting the outside ends of the first boards to the photosensitive chip. The transparent layer placed on the frame layer to cover the photosensitive chip.

According to the invention, the manufacturing cost can be effectively lowered and the production yield can be improved.

### BRIEF DESCRIPTION OF THE DRAWINGS

FIG. 1 is an cross-sectional view showing a conventional package structure for photosensitive chips.

FIG. 2 is a cross-sectional showing an image sensor package of the present invention.

FIG. 3 is a first schematic illustration showing the metal sheets of the image sensor package of the present invention

FIG. 4 is a second schematic illustration showing the metal sheets of the image sensor package of the present invention.

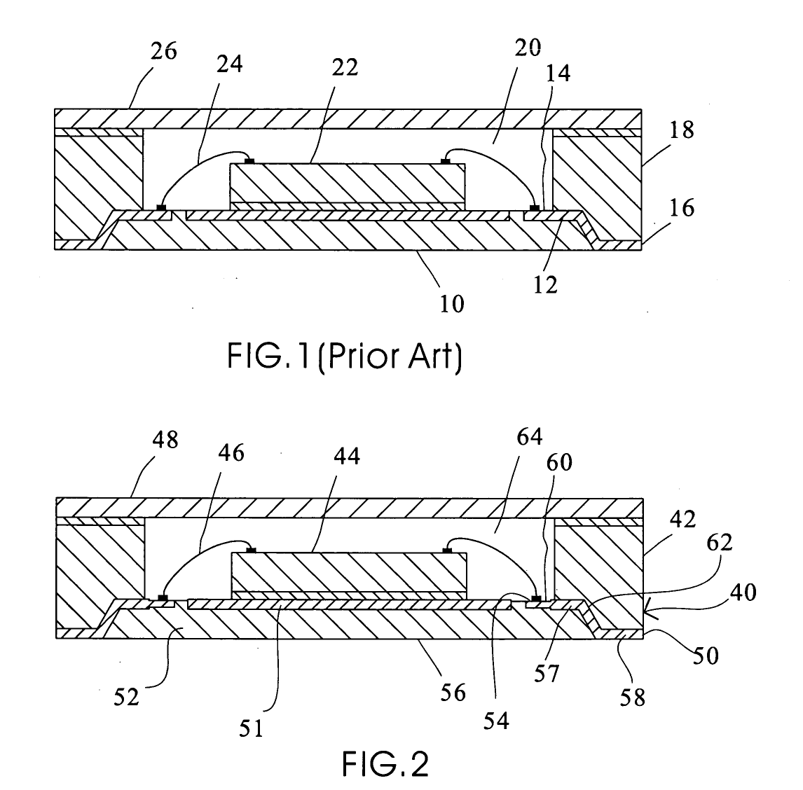

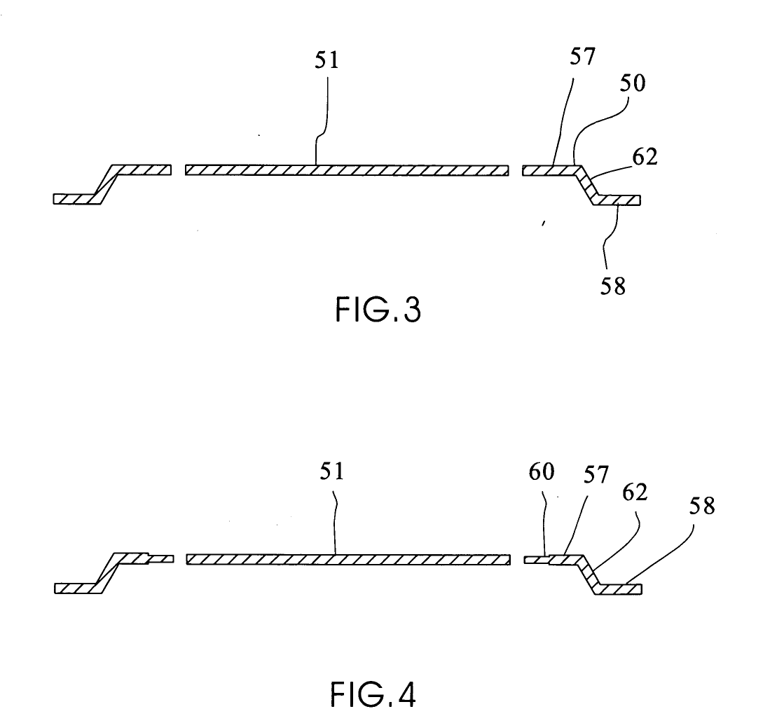

### DETAILED DESCRIPTION OF THE INVENTION

Referring to FIG. 2, the image sensor package in accordance with one embodiment of the invention includes a substrate 40, a frame layer 42, a photosensitive chip 44, a plurality of wires 46 and a transparent layer 48.

The substrate 40 is consisted of a plurality of metal sheets 50 a middle board 51 and a encapsulate layer 52. The metal sheets 50 are arranged in a spaced apart and alternating manner. The middle board 51, which is arranged in the center of a zone enclosed by the metal sheets 50 and apart from the metal sheets 50. Each metal sheet 50 includes a first board 57, a second board 58, and a third board 62 connecting the first board 80 to the second board 82. The first board 57 is higher than the second board 58. That is, the first board 57 and the second board 58 are positioned at different heights. The thick of outside ends of the metal sheets are smaller the inside ends of the first 57. The substrate 40 can be manufactured by way of pressing to form the metal sheets 50, which are spaced apart and arranged in an alternating manner, and the middle board 51 positioned in the middle of the substrate. Thus, the substrate 40 can be manufactured easily. The encapsulate layer 52 encapsulated the metal sheets 50 to form a upper surface 54 and a lower surface 56, so that the outside ends of the first board 57 and the second board 58 are exposed from the encapsulate layer 52.

In this embodiment, the frame layer 42 is directly formed at the periphery of and bottom of the substrate 40, or formed around and under the substrate 40, by injection molding using the thermal plastic material and an injection mold. The frame layer 42 combines the metal sheets 50 with the middle board 51. A cavity 64 is formed between the frame layer 42 and the substrate 40. The outside ends of the top surface of the first board 57 and the bottom surface of the second board 58 are exposed from the frame layer 72. That is, the bottom surface of the first board 57 and the top surface of the second board 58 are covered by the frame layer 42. The bottom surface of the second board 58 is electrically connected to a printed circuit board (not shown).

The photosensitive chip 74 is placed on the middle board 52 and within the cavity 64.

The wires 46 electrically connect the photosensitive chip 44 to the outside ends of the top surfaces of the first boards 57, respectively. Therefore, signals from the photosensitive chip 44 can be transferred to each metal sheet 50 via the wires 46.

The transparent layer 48 may be a piece of transparent glass and may be bonded to the frame layer 42, thereby covering the photosensitive chip 44 that may receive optical signals passing through the transparent layer 48.

According to the structure of the image sensor, the following advantages can be obtained.

1. Since the thicken of the outside ends of the first board 57 is smaller than the inside ends of the first board 57, thus, outside ends of the first board 57 have a smooth surface, it can be manufactured conveniently and improve the product yield.

2. Since using the outside ends the metal sheets 78, which are spaced apart, arranged in an alternating manner, and serve as the contact points for signal outputs, to form the substrate 70, the cost for forming the traces on the substrate in the prior art can be saved. Therefore, the manufacturing cost can be effectively lowered.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

1. An image sensor package, comprising:
a substrate including plural metal sheets, which are spaced apart and arranged in an alternating manner, each of the metal sheets including a first board and a second board positioned at different heights, the thicken of the outside ends of the first board being smaller than the inside ends of the first board, a encapsulate layer being encapsulated the plural metal sheets to form a upper surface and a lower surface, so that the outside ends of the first board and the second board are exposed from the encapsulate layer;
a frame layer formed around and under the substrate to form a cavity with the substrate;
a photosensitive chip positioned on upper surface of the substrate and within the cavity;
a plurality of wires electrically connecting the outside ends of the first boards to the photosensitive chip; and
a transparent layer placed on the frame layer to cover the photosensitive chip.

2. The image sensor package according to claim 1, wherein the frame layer and the encapsulate layer are made of a thermal plastic material by way of injection molding.

3. The image sensor package according to claim 1, wherein the substrate further comprises a middle board, which are arranged in a zone enclosed by the metal sheets and apart form the metal sheets, and the photosensitive chip is placed on the middle board.

4. The image sensor package according to claim 1, wherein the each of outside ends of the first board of the metal sheets can be manufactured by way of pressing.
